(19) United States
(12) Patent Application Publication
(10) Pub. No.: US 2021/0323022 A1
(43) Pub. Date: Oct. 21, 2021

(54) FLUID-DISPENSING APPARATUS

(71) Applicant: ASM Technology Singapore Pte Ltd, Singapore (SG)

(72) Inventors: Kuok Hang MAK, Hong Kong (HK); Tsz Kit YU, Hong Kong (HK)

(21) Appl. No.: 16/852,669

(22) Filed: Apr. 20, 2020

(51) Int. Cl. B05C 17/005

(52) U.S. Cl. CPC B05C 17/00513

(57) ABSTRACT

A dispensing apparatus for the dispensation of a fluid onto a surface, the dispensing apparatus has a nozzle including a main body and a tube holder made of a deformable material installed on the main body. A dispensing tube having a first end from which the fluid is discharged onto the surface and a second end that is immersed in the fluid in use extends through the tube holder, such that the first and second ends are arranged to protrude from opposite ends of the tube holder. The nozzle is configured to be detachably coupled to a syringe-nozzle adaptor having a tubular body by interference fit between the tube holder and the tubular body of the syringe-nozzle adaptor. The syringe-nozzle adaptor is further attachable to a syringe for storing the fluid.

### FIELD OF THE INVENTION

The invention relates to the dispensers for dispensing fluids, and in particular, to such dispensers used in dispensing adhesives that may be filled with small particles.

### BACKGROUND AND PRIOR ART

Dispensing apparatus are used in the semiconductor industry for dispensing processes where a fluid has to be dispensed from a container onto a substrate. There are many types of dispensing apparatus available on the market with different nozzle designs for implementing different dispensing processes.

One of the main dispensing applications in the semiconductor industry relates to die attachment, wherein a particle-filled adhesive is often used to attach a semiconductor die onto a lead frame via the adhesive. When this type of particle-filled adhesive is dispensed, the particles in the adhesive often block the nozzle and this can happen very quickly in the case of a nozzle that has a relatively small inner diameter as compared with the size of the particles in the fluid. Moreover, air that is trapped in the fluid is another cause of nozzle blockage, as an airlock can result from the trapped air. Nozzle blockage has been a long-standing engineering problem, and it has been recognized that conventional nozzles available on the market are prone to clogging.

Specifically, particle-filled adhesives in the form of particle-filled epoxies are widely and commonly used in the semiconductor industry. The rapid growth of the semiconductor industry requires the volume of epoxy dispensed to be in the order of micro-scales or even nano-scales, with excellent volume consistency and precision to fulfil demanding dispensing processes. To dispense such a miniscule amount of epoxy, a nozzle with a small diameter is generally always preferred. However, the particles suspended in the epoxy are more likely to cause nozzle clogging as the ratio of the particle size to nozzle diameter increases.

Much research has been done into the avoidance of clogging in nozzles. One of the most important factors that leads to nozzle blockage is the internal geometry of the nozzle. Two modes of nozzle-clogging have been identified. One is the formation of a clogging bridge which usually takes place near the entrance from one section of the nozzle to another, and another mode is caused by an airlock phenomenon due to air being trapped in the nozzle.

Conventional approaches in the prior art to avoid the formation of a clogging bridge, also known as clogging arch, include tapered bores. Nozzles that feature tapered bores are used very often in many dispensing processes in order to achieve high flow rates, and some nozzle manufacturers have claimed that their tapered-bore nozzles are designed specifically for dispensing particle-filled fluids to prevent the nozzle blockage.

Nozzles may also be blocked due to the presence of trapped air in the epoxy. Many nozzles on the market require purging to expel trapped air before filling the cavity of its interior structure, but purging may instead introduce air bubbles and cannot reliably guarantee that the nozzle is in a void-free condition. Under certain circumstances, air bubbles cannot rise to the liquid surface to escape and are trapped in the liquid due to an insufficient buoyancy force to overcome the surface tension of the liquid. When air bubbles enter the dispensing pathway, the airlock is even more likely to take place, and this may consequently block or slow down the flow of epoxy.

An example of an improved prior art nozzle design for improving the nozzle so as to reduce the problem of clogging is described in US patent publication number 2019/0039085A1, entitled “Clog-Resistant Nozzle Assembly”. A nozzle assembly described therein has a nozzle body with nozzle bore in which a tube holder encased in the nozzle bore of the nozzle body. A dispensing tube is adhered to the tube holder mounted in the nozzle body.

The nozzle body has a rigid outer body, and when the nozzle assembly is mounted onto a syringe, a syringe outlet contacts an outer surface of the nozzle body.

As the aforesaid nozzle assembly is mounted directly onto a syringe, there is little flexibility to significantly vary a fluid path to orientate the dispensing direction differently to adapt to different dispenser-substrate layouts. Furthermore, where the nozzle assembly is mounted to a support structure which is made of a rigid material, as the outer surface of the nozzle body which surrounds the tube holder is made of a rigid material, it is not possible to ensure sealing between the nozzle body and an outlet of the said support structure. This may cause leakage from the support structure and/or formation of air bubbles in the liquid to be dispensed.

It would be beneficial to design a dispensing apparatus which avoids at least some of the aforesaid shortcomings of the prior art.

### SUMMARY OF THE INVENTION

It is thus an object of the invention to seek to provide a dispensing apparatus that is adapted to avoid particle clogging and air locks in a nozzle assembly. It is a further object of the invention to seek to provide a dispensing apparatus which is more versatile, and promotes better sealing between the nozzle assembly and a body on which the nozzle assembly is mounted.

Accordingly, the invention provides a dispensing apparatus for the dispensation of a fluid onto a surface, the dispensing apparatus comprising: a nozzle including a main body and a tube holder made of a deformable material installed on the main body; and a dispensing tube extending through the tube holder, the dispensing tube having a first end from which the fluid is discharged onto the surface, and a second end that is immersed in the fluid in use, the first and second ends being arranged to protrude from opposite ends of the tube holder; a syringe-nozzle adaptor having a tubular body to which the nozzle is configured to be detachably coupled by interference fit between the tube holder and the tubular body of the syringe-nozzle adaptor; and a syringe for storing the fluid, to which the syringe-nozzle adaptor is attachable.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

An exemplary dispensing apparatus for discharging fluids in accordance with the invention will now be described with reference to the accompanying drawings, in which:

FIG. 1 is an isometric view of a nozzle assembly according to the preferred embodiment of the invention;

FIG. 2 is a cross-sectional view of the nozzle assembly of FIG. 1;

FIG. 3 is a side view of the nozzle assembly which has been mounted onto a syringe-nozzle adaptor;

FIG. 4 is a cross-sectional view of the nozzle assembly mounted onto the syringe-nozzle adaptor as shown in FIG. 3; and

FIG. 5 is a cross-sectional view of the syringe-nozzle adaptor which has been mounted onto a syringe.

### DETAILED DESCRIPTION OF THE PREFERRED EMBODIMENT OF THE INVENTION

FIG. 1 is an isometric view of a nozzle assembly 10 according to the preferred embodiment of the invention. The nozzle assembly 10 generally includes a main body 12, which serves as a housing that other parts are assembled onto, and a dispensing tube 14 which is passed through a fixture in the form of a tube holder 16 to fix the dispensing tube 14 in position with respect to the main body 12.

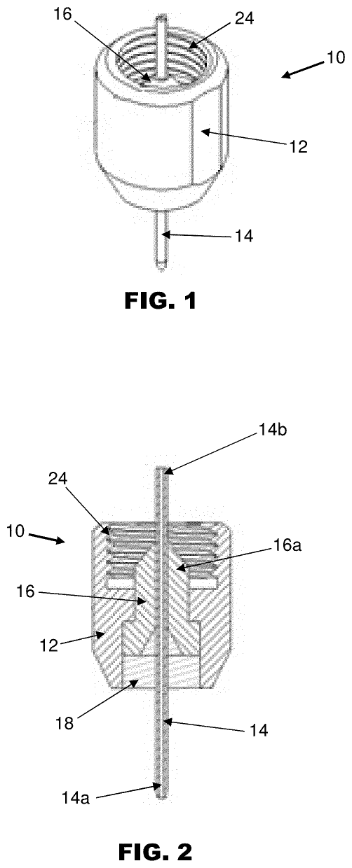

FIG. 2 is a cross-sectional view of the nozzle assembly 10 of FIG. 1. The dispensing tube 14 is centrally-located with respect to the main body 12, and both ends of the dispensing tube 14 protrude from the tube holder 16 through which it has been inserted. Fluid is discharged from a first end 14a of the dispensing tube 14 in use, whereas a second end 14b of the dispensing tube 14 opposite from the first end 14a is immersed in a supply of fluid and receives the fluid to be subsequently discharged through the first end 14a. Main body internal screw threads 24 may be formed on an inner surface of the main body 12 for the purpose of mounting the nozzle assembly 10.

A structural adhesive 18 is injected between the main body 12 and the tube holder 16 for hermetically sealing an interface between the main body 12 and the tube holder 16. Such structural adhesive 18 may be injected only at a base of the tube holder 16, or at both a top and a base of the tube holder 16 for hermetically sealing the interface.

Moreover, a top portion 16a of the tube holder 16 protrudes from an inner surface of the main body 12. Such protruding top portion 16a may have a generally cylindrical portion as well as a conical or frusto-conical shaped tip at its end. The second end 14b of the dispensing tube 14 in turn protrudes from the said top portion 16a or tip of the tube holder 16.

It is noted that the main cylindrical portion of the protruding top portion 16a is designed to directly engage a tubular body as described in further detail below, so as to directly form a seal between it and the tubular body. Moreover, the said conical or frusto-conical shaped tip aids the insertion of the tube holder 16 into the tubular body to form a seal.

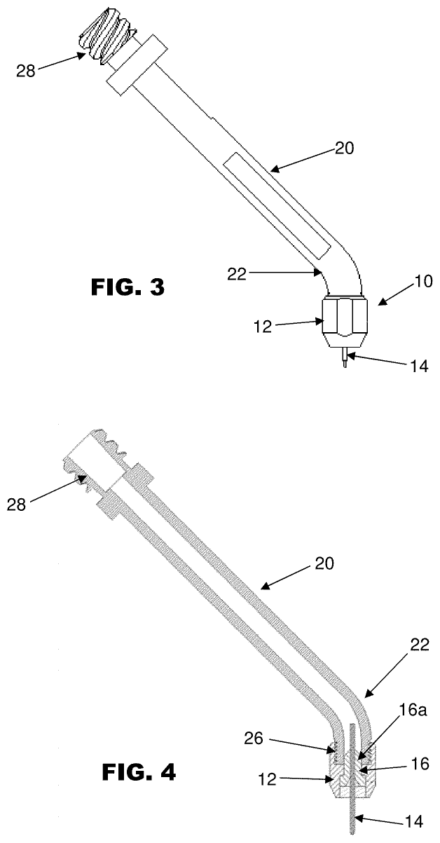

FIG. 3 is a side view of the nozzle assembly 10 which has been mounted onto a syringe-nozzle adaptor 20. The first end 14a of the dispensing tube 14 protrudes from the main body 12 and will be positioned over a substrate in use for discharging fluid onto the substrate.

FIG. 4 is a cross-sectional view of the nozzle assembly 10 mounted onto the syringe-nozzle adaptor 20 of FIG. 3. The syringe-nozzle adaptor 20 comprises an elongated tubular body. The tubular body comprises a bent portion 22 between opposite ends of the syringe-nozzle adaptor 20, preferably nearer to the position of the nozzle assembly 10. The bent portion 22 has a uniform cross-sectional area throughout its length, which ensures a gradual change in direction of a fluidic path of the fluid introduced into the syringe-nozzle adaptor 20. A gradual change of direction of the fluid path facilitates the maintenance of a streamlined passage for the fluid to flow through the tubular body.

It can be seen that when the main body 12 is mounted onto the syringe-nozzle adaptor 20, the top portion 16a of the tube holder 16 is inserted into and engages the tubular body of the syringe-nozzle adaptor 20 by interference fit between the tube holder 16 and the tubular body. Preferably, the tube holder 16 comprises Teflon, which is operative to form a seal between the tube holder 16 and the syringe-nozzle adaptor 20. As such, the top portion 16a of the tube holder is operative to seal a radial interface between the nozzle assembly 10 and the syringe-nozzle adaptor 20, which seal is not present in the prior art. Furthermore, the protruding top portion 16a can serve to remove any cavity that may cause air trapping in the nozzle assembly 10 while fluid is filling the cavity of the nozzle assembly.

It is beneficial to make the tube holder 16 from Teflon, as it is soft and its Young's Modulus is low, such that it is deformable. However, the material is not limited to Teflon, and any other sealing materials with similar mechanical properties which are suitable to be used as a fixture, but is deformable to form a seal with the tubular body, may also be used. As a fixture, the tube holder 16 should secure the tube through interference fit. As a seal, the first portion 16a of the tube holder 16 should be capable of radially sealing the interface between the nozzle assembly 10 and the syringe-nozzle adaptor 20.

Optionally, for the purpose of securing the nozzle assembly 10 onto the syringe-nozzle adaptor 20, mating external screw threads 26 are formed on an outer surface of the tubular body to mate with the main body internal screw threads 24 by screwing the main body 12 onto an end of the syringe-nozzle adaptor 20. By locating the main body internal screw threads 24 outside the tubular body, this ensures that the respective screw threads 24, 26 are not exposed to the fluid that is being discharged. There are also mounting screw threads 28 located at an opposite end of the syringe-nozzle adaptor 20 for mounting the syringe-nozzle adaptor 20 onto a syringe by way of a Luer lock, as described below.

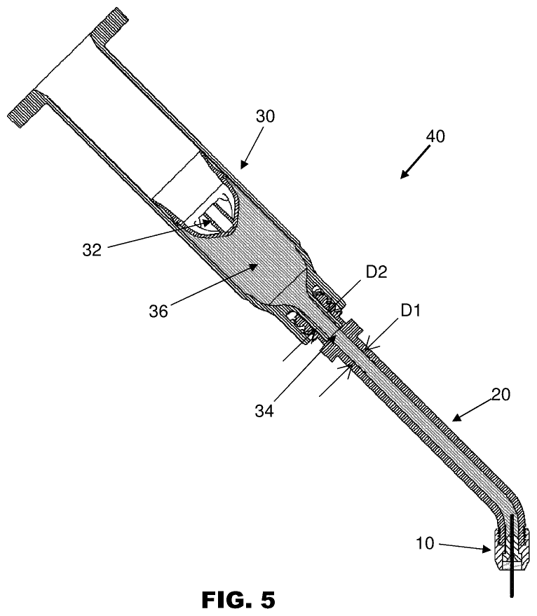

FIG. 5 is a cross-sectional view of the syringe-nozzle adaptor 20 having been mounted onto a syringe 30 to form a dispensing apparatus 40. The syringe 30 is filled with a particle-filled fluid, such as an epoxy 36. The epoxy 36 may be discharged from the syringe 30 into the syringe-nozzle adaptor 20 by exerting a force from a movable piston 32 that pushes against the epoxy 36 in the syringe 30.

The dispensing apparatus 40 is designed such that an inner diameter D1 of the syringe-nozzle adaptor 20 is equal to an inner diameter D2 of an outlet 34 of the syringe 30. Through this design, the inner diameter D1 of the tubular body of the syringe-nozzle adaptor 20 forms a streamlined and uninterrupted passage with a constant cross-section between the tubular body of the syringe-nozzle adaptor 20 and the outlet 34 of the syringe 30.

Preparation of the dispensing apparatus 40 will now be described to explain its use. The syringe-nozzle adaptor 20 is first installed onto the syringe 30 through the Luer lock. The epoxy 36 in the syringe 30 is then purged by applying a force from the piston 32 to fill the dispensing path of the tubular body of the syringe-nozzle adaptor 20 fully with epoxy 36 from the syringe 30. The nozzle assembly 10 is then mounted onto the other end of the syringe-nozzle adaptor 20 by screwing the nozzle assembly 10 thereon, and forming an interference fit between the tube holder 16 and the tubular body of the syringe-nozzle adaptor 20.

It should be appreciated that the protrusion in the nozzle assembly 10 in the form of the top portion 16a of the tube holder 16 removes any cavity that may cause air trapping in the nozzle assembly 10. The need to separately purge the nozzle assembly 10 of air during use is avoided and hence an airlock will not occur to block or slow down the flow of the particle-filled fluid or epoxy 36. Hence, the nozzle assembly 10 mounted on the syringe-nozzle adaptor 20 improves the dispensing performance as the flow of the dispensed fluid is no longer affected by avoiding blockage thereof and the dispensing apparatus 40 operates in a more stable manner.

This dispensing assembly 40 as described in the preferred embodiment of the invention can resolve the problem of nozzle blockage and to improve the performance of dispensing particle-filled fluid. The nozzle assembly 10 according to the invention prevents both clogging bridges and airlocks, which are the fundamental causes of nozzle blockage. Since the likelihood of blockage in the dispensing pathway of the nozzle assembly 10 is obviated, the flow rate of discharged fluid becomes more stable, and consequently, the dispensed volume will become more consistent.

It is also relatively easy to clean the nozzle assembly 10 in a timely manner, and the nozzle assembly 10 can be restored for reuse due to its easy-to-access geometry, since the tube holder 16 is adapted to directly engage the tubular body of the syringe-nozzle adaptor 20 to form a seal. On the contrary, reuse of conventional nozzles on the market is not encouraged due to the difficulty in cleaning them.

Although the syringe-nozzle adaptor 20 has been illustrated with a bent portion 22, its construction is not limited to that illustrated. The elongated tubular body may thus be straight, or if there is a bent, it may be bent in any other orientations and/or at any angle.

The invention described herein is susceptible to variations, modifications and/or additions other than those specifically described and it is to be understood that the invention includes all such variations, modifications and/or additions which fall within the spirit and scope of the above description.

1. A dispensing apparatus for the dispensation of a fluid onto a surface, the dispensing apparatus comprising:
a nozzle including:
a main body and a tube holder made of a deformable material installed on the main body; and
a dispensing tube extending through the tube holder, the dispensing tube having a first end from which the fluid is discharged onto the surface, and a second end that is immersed in the fluid in use, the first and second ends being arranged to protrude from opposite ends of the tube holder;
a syringe-nozzle adaptor having a tubular body to which the nozzle is configured to be detachably coupled by interference fit between the tube holder and the tubular body of the syringe-nozzle adaptor; and
a syringe for storing the fluid, to which the syringe-nozzle adaptor is attachable.

2. The dispensing apparatus as claimed in claim 1, wherein the tube holder comprises Teflon, which is operative to form a seal directly between the tube holder and the syringe-nozzle adaptor.

3. The dispensing apparatus as claimed in claim 2, wherein the tube holder is operative to seal a radial interface between the nozzle and the syringe-nozzle adaptor.

4. The dispensing apparatus as claimed in claim 1, wherein an inner diameter of the syringe-nozzle adaptor is equal to an inner diameter of an outlet of the syringe.

5. The dispensing apparatus as claimed in claim 4, wherein the inner diameter of the syringe-nozzle adaptor forms a streamlined and uninterrupted passage with a constant cross-section between the syringe-nozzle adaptor and the outlet of the syringe.

6. The dispensing apparatus as claimed in claim 4, further comprising screw threads located on the syringe-nozzle adaptor for mounting the syringe-nozzle adaptor onto the syringe.

7. The dispensing apparatus as claimed in claim 1, further comprising internal screw threads on an inner surface of the main body for mounting onto mating external screw threads formed on an outer surface of the tubular body.

8. The dispensing apparatus as claimed in claim 1, further comprising a structural adhesive injected between the main body and the tube holder for hermetically sealing an interface between the main body and the tube holder.

9. The dispensing apparatus as claimed in claim 1, wherein the tubular body is elongated and comprises a bent portion between opposite ends of the syringe-nozzle assembly.

10. The dispensing apparatus as claimed in claim 9, wherein the bent portion has a uniform cross-sectional area through its length and forms a gradual change in direction of a fluidic path of the fluid introduced into the syringe-nozzle adaptor.

11. The dispensing apparatus as claimed in claim 1, wherein a top portion of the tube holder from which the second end of the dispensing tube protrudes has a conical or frusto-conical shaped end.
